(19) United States
(12) Patent Application Publication
(10) Pub. No.: US 2012/0262147 A1
(43) Pub. Date: Oct. 18, 2012

(54) Method for compensating timing offset in calibration of AC voltage level switching in relay and computer program product thereof

(75) Inventor: Chih-Hung Wang, New Taipei (TW)

(73) Assignee: GOOD WAY TECHNOLOGY CO., LTD, New Taipei (TW)

(21) Appl. No.: 13/087,030

(22) Filed: Apr. 14, 2011

(51) Int. Cl. G01R 19/00

(52) U.S. Cl. 324/76.11

(57) ABSTRACT

A method for compensating a timing offset in calibration of AC (alternating current) voltage level switching in a relay and a computer program product thereof are introduced. The method involves performing timing detection of electrical connection/disconnection of the relay at a zero-voltage crossing point by a controlling unit and detecting circuits disposed at input and output ends of the relay, respectively, calculating a timing offset compensation value according to a temporal difference between a point in time of the switching of the relay and the zero-voltage crossing point, and obtaining an accurate response time of the relay to electrical connection/disconnection thereof according to the timing offset compensation value, such that the electrical disconnection/connection of the relay calibrated by the controlling unit coincides with the zero-voltage crossing point to avoid instantaneous high current charging and preclude a spark which is likely to end up in electrical disconnection.

### FIELD OF THE INVENTION

The present invention relates to a method for compensating a timing offset in a relay and a computer program product thereof, in particular to a method for obtaining a time parameter of timing in calibration of AC (alternating current) voltage level switching in a relay and a computer program product thereof.

### BACKGROUND OF THE INVENTION

A relay is an electronic control apparatus which comprises a controlling system (an input circuit) and a controlled system (an output circuit) and is widely applicable to various electrical apparatuses. In practice, a relay functions as an automatic switch for controlling a high current by means of a low current, and thus a relay which is disposed in a circuit is capable of automatic regulation, security-enhancing protection, and circuit transformation.

With a relay operating by controlling the ON and OFF of a contact according to whether a coil is magnetized or not, a relay can only be electrically connected or disconnected when a specific response time period from the magnetization of the relay has passed. However, after the aforesaid delay, a relay is likely to be electrically connected or disconnected at a high voltage level in the absence of satisfactory timing control; as a result, the relay is likely to generate a spark at the instant when the contact is electrically connected or disconnected, thereby ending up with various hazards and instability of apparatuses. Nonetheless, relays mostly differ in the response time of electrical connection or disconnection, thereby adding to the difficulty in designing a circuit for controlling the electrical connection or disconnection of relays and effectuating the mass production of the circuit.

### SUMMARY OF THE INVENTION

It is a primary objective of the present invention to provide a method for compensating a timing offset in automatic calibration of AC (alternating current) voltage level switching in a relay and a computer program product thereof for controllably ensuring that the electrical connection or disconnection of the relay occurs at a voltage level of 0V so as to avoid instantaneous high current charging and preclude a spark which is likely to end up in electrical disconnection.

Another objective of the present invention is to provide a way of detecting each time parameter value of the relay automatically rather than selecting a relay material from specific materials corresponding to given time parameters, respectively, so as to be applicable to mass production of relay-specific control circuits and applicable to relays made of different materials.

In order to achieve the above and other objectives, the present invention provides a method for obtaining a time parameter. The method comprises the steps of: a. obtaining from an input side of the relay a half-wave period for use as an input source; b. switching a state of the relay with a first point in time defined as the half-wave period as soon as the half-wave period of the phase timing on the input side of the relay matches a zero-voltage crossing point for switching between high and low voltage levels; c. switching a state of the relay with a second point in time defined as the half-wave period as soon as the half-wave period of the phase timing on the output side of the relay matches a zero-voltage crossing point for switching between high and low voltage levels; and d. switching a state of the relay with a third point in time defined as the half-wave period as soon as the half-wave period of the phase timing on the output side of the relay matches a zero-voltage crossing point for switching between high and low voltage levels; wherein a response time parameter of the relay is obtained according to the first point in time and the second point in time, and a compensation time parameter of the relay is obtained according to the second point in time and the third point in time.

The present invention provides a method for compensating a timing offset in automatic calibration of AC voltage level switching in a relay. The method comprises the step of obtaining a time parameter data pertaining to the electrical connection and electrical disconnection of the relay, so as to control the operation of the electrical connection and electrical disconnection of the relay.

The method for obtaining a time parameter data pertaining to the electrical connection of the relay comprises the steps of: obtaining from an input side of the relay a half-wave period for use as an input source; enabling the relay with a first start timing reference point defined as the first point in time as soon as the phase timing on the input side of the relay matches a zero-voltage crossing point of switching from a low voltage level to a high voltage level; obtaining a first electrical connection response time value starting from the first start timing reference point to a first electrical connection timing reference point, wherein the first electrical connection timing reference point is a point in time when the phase timing on the output side of the relay matches a zero-voltage crossing point of switching from a low voltage level to a high voltage level, wherein the first electrical connection timing reference point is defined as the second point in time; obtaining a first electrical connection compensation time value starting from the first electrical connection timing reference point to a timing reference point, wherein the timing reference point is a point in time when the phase timing on the output side of the relay matches a zero-voltage crossing point of switching from a high voltage level to a low voltage level, wherein the timing reference point is defined as the third point in time; and determining a relationship between the first electrical connection compensation time value and the half-wave period, followed by determining that a time parameter required for electrical connection of the relay includes the first electrical connection response time value and the first electrical connection compensation time value when the first electrical connection compensation time value is less than the half-wave period.

In an embodiment, determining a relationship between the first electrical connection compensation time value and the half-wave period further comprises performing, upon determination that the first electrical connection compensation time value is not less than the half-wave period, the sub-steps of: disabling and electrically disconnecting the relay upon determination that the phase timing on one of the input side and the output side of the relay matches a zero-voltage crossing point of switching from a high voltage level to a low voltage level; enabling the relay with a second start timing reference point defined as a zero-voltage crossing point of switching from a high voltage level to a low voltage level as soon as the phase timing on the input side of the relay matches the zero-voltage crossing point; obtaining a second electrical connection response time value starting from the second start timing reference point to a second electrical connection timing reference point, wherein the second electrical connection timing reference point is a point in time when the phase timing on the output side of the relay matches a zero-voltage crossing point of switching from a low voltage level to a high voltage level; obtaining a second electrical connection compensation time value starting from the second electrical connection timing reference point to a timing reference point, wherein the timing reference point is a point in time when the phase timing on the output side of the relay matches a zero-voltage crossing point of switching from a high voltage level to a low voltage level; and determining a relationship between the second electrical connection compensation time value and the half-wave period, followed by determining that a time parameter required for electrical connection of the relay includes the second electrical connection response time value and the second electrical connection compensation time value when the second electrical connection compensation time value is less than the half-wave period.

In an embodiment, determining a relationship between the second electrical connection compensation time value and the half-wave period further comprises determining that a time parameter required for electrical connection of the relay is the second electrical connection response time value and that the second electrical connection compensation time value equals zero, when the second electrical connection compensation time value equals the half-wave period or equals two times the half-wave period.

In order to achieve the above and other objectives, the present invention provides a method for obtaining a time parameter data required for the electrical disconnection of the relay. The method comprises the steps of: defining the third start timing reference point as a zero-voltage crossing point of switching from a low voltage level to a high voltage level, followed by disabling the electrically connected relay, as soon as the phase timing on one of the input side and the output side of the relay matches the zero-voltage crossing point; obtaining the first electrical disconnection response time value starting from the third start timing reference point to the first electrical disconnection timing reference point, wherein the first electrical disconnection timing reference point is a point in time when the phase timing on the output side of the relay matches a zero-voltage crossing point of switching from a high voltage level to a low voltage level, wherein the obtaining the first electrical disconnection response time value further comprises determining whether the relay is electrically disconnected according to a voltage level of the output side of the relay when the phase timing on the input side of the relay matches a high voltage level; obtaining the first electrical disconnection compensation time value starting from the first electrical disconnection timing reference point to a timing reference point, wherein the timing reference point is a point in time when the phase timing on the input side of the relay matches a zero-voltage crossing point of switching from a high voltage level to a low voltage level; and determining a relationship between the first electrical disconnection compensation time value and the half-wave period, followed by determining that a time parameter required for electrical disconnection of the relay includes the first electrical disconnection response time value and the first electrical disconnection compensation time value when the first electrical disconnection compensation time value is less than the half-wave period.

In an embodiment, the determining a relationship between the first electrical disconnection compensation time value and the half-wave period further comprises performing, upon determination that the first electrical disconnection compensation time value is not less than the half-wave period, the sub-steps of: enabling the relay as soon as the phase timing on the input side of the relay matches a zero-voltage crossing point of switching from a high voltage level to a low voltage level; disabling the relay with a fourth start timing reference point defined as a zero-voltage crossing point of switching from a high voltage level to a low voltage level upon determination that the phase timing on the output side of the relay matches the zero-voltage crossing point or upon determination that the phase timing on the input side of the relay matches the zero-voltage crossing point again; obtaining a second electrical disconnection response time value starting from the fourth start timing reference point to a second electrical disconnection timing reference point, wherein the second electrical disconnection timing reference point is a point in time when the phase timing on the output side of the relay matches a zero-voltage crossing point of switching from a high voltage level to a low voltage level; obtaining a second electrical disconnection compensation time value starting from the second electrical disconnection timing reference point to a timing reference point, wherein the timing reference point is a point in time when the phase timing on the input side of the relay matches a zero-voltage crossing point of switching from a high voltage level to a low voltage level; and determining a relationship between the second electrical disconnection compensation time value and the half-wave period, followed by determining that a time parameter required for electrical disconnection of the relay includes the second electrical disconnection response time value and the second electrical disconnection compensation time value when the second electrical disconnection compensation time value is less than the half-wave period.

In an embodiment, the determining a relationship between the first electrical disconnection compensation time value and the half-wave period further comprises performing, upon determination that the first electrical disconnection compensation time value is not less than the half-wave period, the sub-steps of: enabling the relay as soon as the phase timing on the input side of the relay matches a zero-voltage crossing point of switching from a high voltage level to a low voltage level; disabling the relay with a fifth start timing reference point defined as a zero-voltage crossing point of switching from a high voltage level to a low voltage level upon determination that the phase timing on the output side of the relay matches the zero-voltage crossing point or upon determination that the phase timing on the input side of the relay matches the zero-voltage crossing point again; obtaining a third electrical disconnection response time value starting from the fifth start timing reference point to a third electrical disconnection timing reference point, wherein the third electrical disconnection timing reference point is a point in time when the phase timing on the input side of the relay matches a high voltage level again and the phase timing on the output side of the relay does not match a high voltage level; obtaining a third electrical disconnection compensation time value starting from the third electrical disconnection timing reference point to a timing reference point, wherein the timing reference point is a point in time when the phase timing on the input side of the relay matches a zero-voltage crossing point of switching from a high voltage level to a low voltage level; and determining a relationship between the third electrical disconnection compensation time value and the half-wave period, followed by determining that a time parameter required for electrical disconnection of the relay is the third electrical disconnection response time value and that the third electrical disconnection compensation time value equals zero, when the third electrical disconnection compensation time value equals the half-wave period or equals two times the half-wave period.

In an embodiment, on the input side of the relay, an input source of an AC sine wave is transformed into a half-wave rectified square wave so as to obtain the half-wave period.

Accordingly, given a controlling unit and input and output detecting ends of a relay, and the control of the electrical connection and disconnection of the relay, it is easy to obtain a time parameter of the relay during a manufacturing process without the hassle of measuring a response time required for the electrical connection and electrical disconnection of the relay in advance and then specifying a raw materials for use in production.

### BRIEF DESCRIPTION OF THE DRAWINGS

To enable persons skilled in the art to fully understand the objectives, features, and advantages of the present invention, the present invention is hereunder illustrated with specific embodiments in conjunction with the accompanying drawings, in which:

FIG. 1 is a block diagram of a control circuit according to an embodiment of the present invention;

FIG. 2 is a timing schematic view of a method for obtaining an electrical connection time parameter of timing in calibration of AC (alternating current) voltage level switching according to an embodiment of the present invention; and

FIG. 3 is a timing schematic view of a method for obtaining an electrical disconnection time parameter of timing in calibration of AC voltage level switching according to an embodiment of the present invention.

### DETAILED DESCRIPTION OF THE PREFERRED EMBODIMENTS

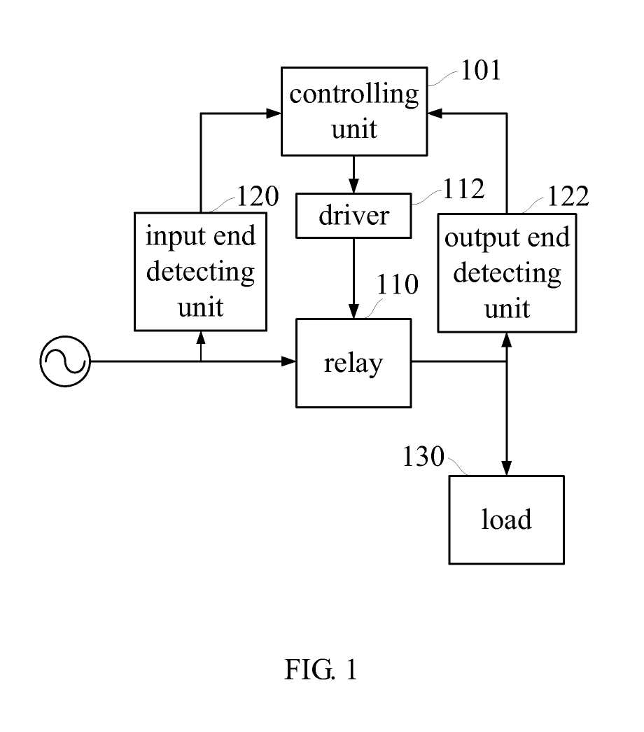

Please refer to FIG. 1 for a block diagram of a control circuit according to an embodiment of the present invention. As shown in FIG. 1, a driver 112 drives the electrical connection (when the driver 112 magnetizes the relay 110) and electrical disconnection (when the driver 112 demagnetizes the relay 110) of a relay 110. An input end detecting unit 120 and an output end detecting unit 122 detect voltage level timing at a power input end and a power output end of the relay 110, respectively, and transmit the obtained timing data to a controlling unit 101 connected to the input end detecting unit 120 and the output end detecting unit 122. The controlling unit 101 is configured to perform a method for obtaining a time parameter of timing in calibration of AC (alternating current) voltage level switching according to the present invention, and store the obtained timing data in a memory of the controlling unit 101 such that, when the relay provides a load 130, the stored timing data enables the controlling unit 101 to cause both the electrical connection and the electrical disconnection of the relay to happen at a point in time when the voltage level is low, such as the zero-voltage point, so as to prevent a spark.

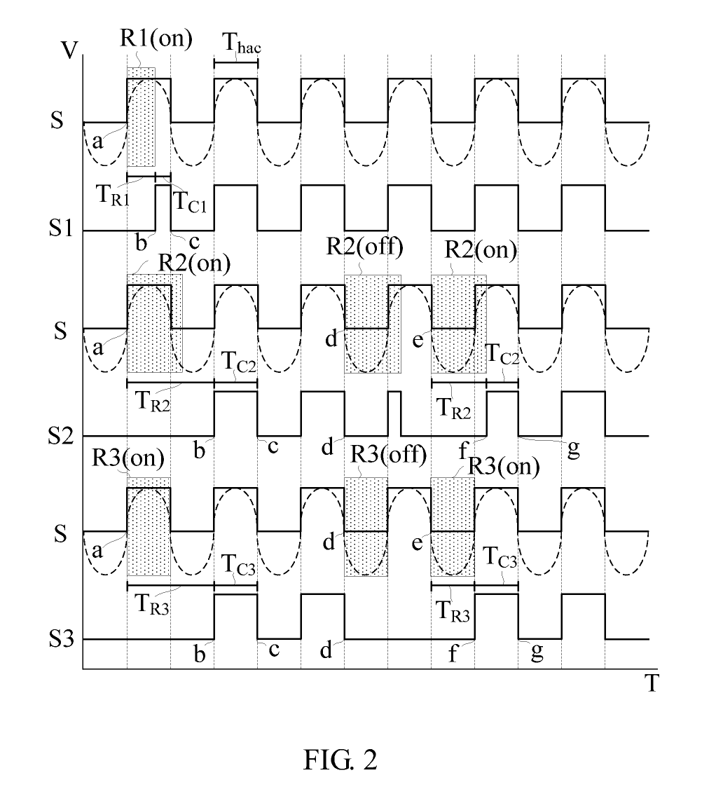

Please refer to FIG. 2 for a timing schematic view of a method for obtaining an electrical connection time parameter of timing in calibration of AC voltage level switching according to an embodiment of the present invention, where the horizontal axis represents time T, and the vertical axis represents voltage level V. According to the present invention, an input source of an AC sine wave is transformed into a half-wave rectified square wave S shown in the drawing. The aforesaid transformation can be effectuated by a detecting unit. For example, a high voltage level can be replaced with a low voltage level by means of large-resistance voltage drop as a result of a series-connection, and then transformation of the AC sine wave into the half-wave rectified square wave can be achieved by means of the high and low triggering of a transistor, which are known electronic techniques and thus are omitted from the description herein for the sake of brevity. As shown in FIG. 2, with a logic inverter, the half-wave rectified square wave is transformed to enter a zero-voltage state whenever a high-voltage point of the AC sine wave appears.

As shown in FIG. 2, after the AC sine wave has been transformed into the half-wave rectified square wave, the half-wave period becomes T_{hac}, and the square wave features a zero-voltage crossing point allowing the transition from Low to High or the transition from High to Low. According to the present invention, determination of different states is carried out by making reference to the crossing points and a zero-voltage crossing point at the output end of the relay. A response time (i.e., a period of time from magnetization to electrical connection of the relay, or a period of time from demagnetization to electrical disconnection of the relay) depends on the brand or the constituent material of the relay, and thus magnetization occurs in accordance with three different relay electrical connection response times as follows: the relay electrical connection response time R1 which is less than the half-wave period T_{hac}; the relay electrical connection response time R2 which is larger than the half-wave period T_{hac}; and the relay electrical connection response time R3 which equals the half-wave period T_{hac}. The aforesaid three conditions apply to demagnetization too.

A method for obtaining a time parameter according to the present invention comprises the steps of:
a. obtaining from the input side of the relay a half-wave period for use as an input source;
b. switching a state of the relay with a first point in time defined as the half-wave period as soon as the half-wave period of the phase timing on the input side of the relay matches a zero-voltage crossing point for switching between high and low voltage levels;
c. switching a state of the relay with a second point in time defined as the half-wave period as soon as the half-wave period of the phase timing on the output side of the relay matches a zero-voltage crossing point for switching between high and low voltage levels; and
d. switching a state of the relay with a third point in time defined as the half-wave period as soon as the half-wave period of the phase timing on the output side of the relay matches a zero-voltage crossing point for switching between high and low voltage levels,
   wherein it is feasible to obtain a response time parameter of the relay according to the first point in time and the second point in time and obtain a compensation time parameter of the relay according to the second point in time and the third point in time.

The method for obtaining a time parameter according to the present invention is hereunder described in detail by making reference to related drawings.

Referring to FIG. 2, with the relay electrical connection response time R1, a procedure for operating the controlling unit 101 comprises the steps of:
A1. detecting the phase timing on the input end of the relay 110 (equivalent to detecting the phase timing of the square wave S) by the input end detecting unit 120 shown in FIG. 1 after a half-wave period T_{hac} of an input source has been obtained, followed by enabling the relay as soon as a point in time of the phase timing matches a zero-voltage crossing point of switching from a low voltage level to a high voltage level (that is, a point in time a at which the controlling unit 101 records the value of every specific point in time such that the recorded value of every specific point in time can be used in subsequent calculation, and the term “the point in time a” is also known as “a first start timing reference point”);
A2. detecting the phase timing on the output end of the relay 110 by the output end detecting unit 122 shown in FIG. 1, wherein a first electrical connection response time value T_{R1} of the relay is obtained according to the temporal difference between the point in time a and a point in time b as soon as the phase timing on a square wave S1 at the output side of the relay matches a point in time of switching from a low voltage level to a high voltage level, that is, the point in time b (that is, a first electrical connection timing reference point);
A3. detecting the phase timing on the output end of the relay 110 by the output end detecting unit 122 shown in FIG. 1, wherein a first electrical connection compensation time value T_{C1} of the relay is obtained according to the temporal difference between a point in time c and the point in time b as soon as the phase timing on the square wave S1 at the output side of the relay matches a point in time of switching from a high voltage level to a low voltage level, that is, the point in time c; and
A4. determining the relationship between a first electrical connection compensation time value T_{R1} and the half-wave period T_{hac}, followed by determining that a time parameter required for the electrical connection of the relay includes the first electrical connection response time value T_{R1} and the first electrical connection compensation time value T_{C1} when the first electrical connection compensation time value T_{R1} is less than the half-wave period T_{hac}.

Accordingly, the controlling unit 101 obtains a time parameter required for the magnetization and resultant electrical connection of the relay and stores the obtained time parameter therein. Afterward, every instance of the magnetization and resultant electrical connection of the relay results in a product of an odd integral (exemplified by 1 in an embodiment of the present invention) and the half-wave period T_{hac}, with the product being equal to the sum of the first electrical connection response time value T_{R1} and the first electrical connection compensation time value T_{C1}; hence, once the phase timing on the input side of the relay matches a zero-voltage crossing point, the controlling unit 101 can reach the first electrical connection compensation time value T_{C1} and then controllably cause the driver 112 to magnetize the relay 110. In doing so, a low voltage level occurs at the final point of the electrical connection of the relay, thereby preventing a spark.

As shown in FIG. 2, it is impossible to determine a response time and a compensation time of the relay electrical connection response time R2, R3 in the aforesaid steps accurately, (as indicated by a marked difference between the measured response time and the actual response time in FIG. 2). Hence, regarding the relay electrical connection response time R2 of the relay, the step of determining the relationship between the first electrical connection compensation time value T_{C1} and the half-wave period T_{hac} at point A4 further comprises: operating the controlling unit 101 when the first electrical connection compensation time value T_{C1} (that is, T_{C2} in FIG. 2) is not less than the half-wave period T_{hac} by taking the steps of:
B1. disabling the relay having the relay electrical connection response time R2 upon determination that the phase timing on one of the input side and the output side of the relay having the relay electrical connection response time R2 matches a zero-voltage crossing point (that is, a point in time d) of switching from a high voltage level to a low voltage level;
B2. enabling the relay having the relay electrical connection response time R2 upon determination that the phase timing on the input side of the relay having the relay electrical connection response time R2 matches a zero-voltage crossing point (that is, a point in time e, also known as “a second start timing reference point”) of switching from a high voltage level to a low voltage level;
B3. obtaining a second electrical connection response time value T_{R2} of the relay having the relay electrical connection response time R2 according to a temporal difference between a point in time f and the point in time e of the enabled relay having the relay electrical connection response time R2 when the phase timing on the output side of the relay having the relay electrical connection response time R2 matches a zero-voltage crossing point (that is, the point in time f, also known as “a second electrical connection timing reference point”) of switching from a low voltage level to a high voltage level;
B4. obtaining a second electrical connection compensation time value T_{C2} of the relay having the relay electrical connection response time R2 according to a temporal difference between the point in time f and a point in time g of the enabled relay having the relay electrical connection response time R2 when the phase timing on the output side of the relay having the relay electrical connection response time R2 matches a zero-voltage crossing point (that is, the point in time g) of switching from a high voltage level to a low voltage level;
B5. determining the relationship between the second electrical connection compensation time value T_{C2} and the half-wave period T_{hac}, followed by determining that a time parameter required for the electrical connection of the relay having the relay electrical connection response time R2 includes the second electrical connection response time value T_{R2} and the second electrical connection compensation time value T_{C2} when the second electrical connection compensation time value T_{C2} is less than the half-wave period T_{hac}.

Accordingly, the controlling unit 101 obtains a time parameter of the relay having the relay electrical connection response time R2 and stores the obtained time parameter therein. Afterward, every instance of the magnetization and resultant electrical connection of the relay results in a product of an even integral (exemplified by 2 in an embodiment of the present invention) and the half-wave period T_{hac}, with the product being equal to the sum of the second electrical connection response time value T_{R2} and the second electrical connection compensation time value T_{C2}; hence, once the phase timing on the input side of the relay matches a zero-voltage crossing point, the controlling unit 101 can reach the second electrical connection compensation time value T_{C2} and then controllably cause the driver 112 to magnetize the relay 110. In doing so, a low voltage level occurs at the final point of the electrical connection of the relay, thereby preventing a spark.

As shown in FIG. 2, the relay having the relay electrical connection response time R3 is more or less in agreement with the relay having the relay electrical connection response time R2, except that an embodiment of the relay having the relay electrical connection response time R3 is distinctly characterized in that the step B5 of determining the relationship between a third electrical connection compensation time value T_{C3} and the half-wave period T_{hac} further comprises: determining that a time parameter required for the electrical connection of the relay having the relay electrical connection response time R3 is the third electrical connection response time value T_{R3}, and that the third electrical connection compensation time value T_{C3} equals zero, when the third electrical connection compensation time value T_{C3} equals the half-wave period T_{hac}. It is because the response time of the relay having the relay electrical connection response time R3 is equivalent to the half-wave period T_{hac}, and thus a compensation-based means of control is not required. All the controlling unit 101 has to do is to controllably cause the starting point of the magnetization of the relay having the relay electrical connection response time R3 to coincide with the zero-voltage crossing point of the phase timing on the input side of the relay; in doing so, a low voltage level occurs at a point in time of the magnetization and resultant electrical connection of the relay having the relay electrical connection response time R3 for certain. The terms and reference numerals “third electrical connection response time value T_{R3} and third electrical connection compensation time value T_{C3}” serve an illustrative purpose only and are replaced with the terms “second electrical connection response time value” and “second electrical connection compensation time value” hereunder, respectively.

The method for obtaining a time parameter required for the magnetization and resultant electrical connection of the relay is described above. In general, the process of magnetization and resultant electrical connection at a high voltage level produces more sparks than the process of demagnetization and result electrical disconnection at a high voltage level does. Hence, in a preferred embodiment, a method for obtaining a time parameter required for the demagnetization and result electrical disconnection of the relay is further provided.

Likewise, the demagnetization and result electrical disconnection occurs in accordance with any of the three different relay electrical disconnection response times as follows: relay electrical disconnection response time r1 which is less than the half-wave period T_{hac}; relay electrical disconnection response time r2 which is larger than the half-wave period T_{hac}; and relay electrical disconnection response time r3 which equals the half-wave period T_{hac}.

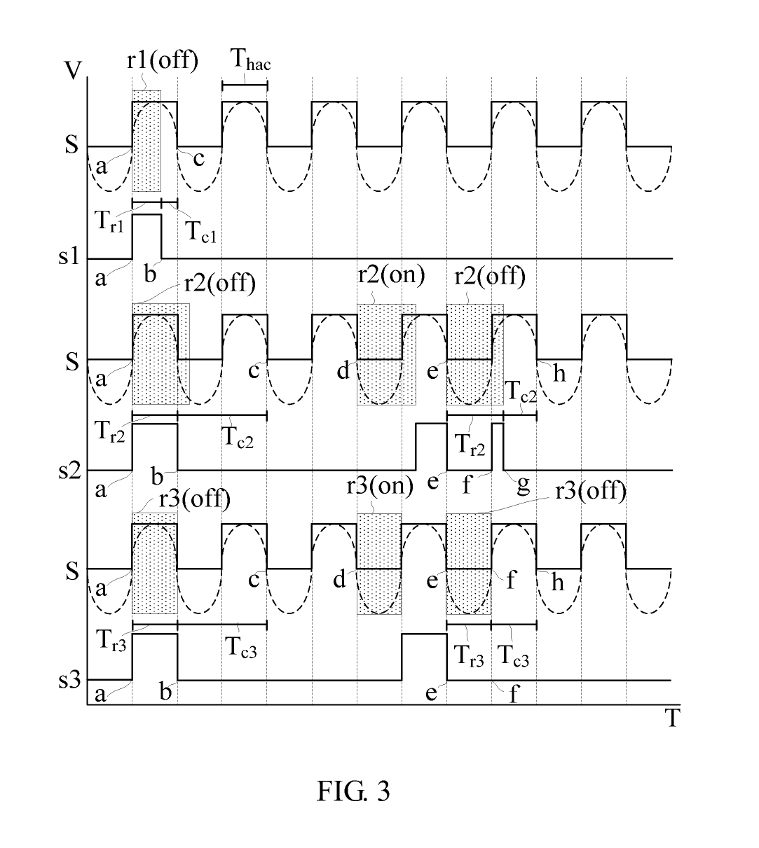

Please refer to FIG. 3 for a timing schematic view of a method for obtaining an electrical disconnection time parameter of timing in calibration of AC voltage level switching according to an embodiment of the present invention. Electrical disconnection is determined against criteria as follows: detecting a square wave voltage level at the input side and the output side of the relay, and determining the accuracy of the electrical disconnection of the relay according to different voltage levels.

As shown in FIG. 3, with the relay electrical disconnection response time r1, a procedure for operating the controlling unit 101 comprises the steps of:
a1. disabling the relay upon determination that the phase timing on one of the input side and the output side of the relay electrically connected matches a zero-voltage crossing point (that is, a point in time a, also known as “a third start timing reference point”) of switching from a low voltage level to a high voltage level;
a2. obtaining a first electrical disconnection response time value Tᵣ₁ of the relay according to the temporal difference between the point in time a and the point in time b (that is, a first electrical disconnection timing reference point) of the disabled relay when the phase timing on the output side of the relay matches the point in time b of switching from a high voltage level to a low voltage level, wherein, prior to obtaining the point in time b (or in step a2), it is also feasible to determine whether the electrical disconnection response time is less than three times the T_{hac} value, wherein the determination that the electrical disconnection response time is equal to or larger than three times the T_{hac} value indicates that the relay has an intrinsic defect and thus is followed by discarding the relay, otherwise (i.e., upon determination that the electrical disconnection response time is less than three times the T_{hac} value), go to the steps pertaining to the relay having the relay electrical disconnection response time r2, so as to calculate the reference compensation for another phase;
a3. determining whether the relay is electrically disconnected according to the high-voltage phase timing on the input side of the relay; for example, where the input side of the relay reaches a high voltage level again after step a2 but the output side of the relay has not increased to a high voltage level, this indicates that the relay has been precisely electrically disconnected, and thus indicates that the electrical disconnection response time is less than or equal to two times the T_{hac} value; conversely, where the input side of the relay reaches a high voltage level again after step a2 but the output side of the relay has been increased to a high voltage level, this indicates that the relay has not been precisely electrically disconnected, and thus indicates that the electrical disconnection response time is larger than two times the T_{hac} value; afterward, timing continues, ending up in any of the two scenarios below; in the first scenario, the output side of the relay does not decrease to a low voltage level until after the input side of the relay decreases from a high voltage level to a low voltage level again, which indicates that the electrical disconnection response time of the relay is larger than or equal to three times the T_{hac} value, and thus indicates that the relay has an intrinsic defect that justifies the discard of the relay; in another scenario, the output side of the relay decreases to a low voltage level before the input side of the relay decreases from a high voltage level to a low voltage level gain, which indicates that the electrical disconnection response time of the relay is less than three times the T_{hac} value;
a4. obtaining the first electrical disconnection compensation time value T_{c1} of the relay according to a temporal difference between the point in time b and the point in time c in switching from a high voltage level to a low voltage level during the phase timing on the output side of the relay when the phase timing on the input side of the relay matches the point in time c of switching from a high voltage level to a low voltage level; and
a5. determining the relationship between the first electrical disconnection compensation time value T_{c1} and the half-wave period T_{hac}, followed by determining that a time parameter required for electrical disconnection of the relay includes the first electrical disconnection response time value Tᵣ₁ and the first electrical disconnection compensation time value T_{c1} when the first electrical disconnection compensation time value T_{c1} is less than the half-wave period T_{hac}.

Accordingly, the controlling unit 101 obtains a time parameter required for the demagnetization and resultant electrical disconnection of the relay and stores the obtained time parameter therein. Afterward, every instance of demagnetization and resultant electrical disconnection of the relay results in a product of an odd integral (exemplified by 1 in an embodiment of the present invention) and the half-wave period. T_{hac}, with the product being equal to the sum of the first electrical disconnection response time value Tᵣ₁ and the first electrical disconnection compensation time value T_{c1} hence, prior to the zero-voltage crossing point of the phase timing on the input side of the relay, the controlling unit 101 reaches the first electrical disconnection compensation time value T_{c1} and then controllably causes the driver 112 to demagnetize the relay 110. In doing so, a low voltage level occurs at the final point of electrical disconnection of the relay, thereby preventing a spark.

As shown in FIG. 3, it is impossible to determine a response time and a compensation time of the relay electrical disconnection response time r2, r3 in the aforesaid steps accurately, (as indicated by a marked difference between the measured response time and the actual response time in FIG. 3, wherein the output side and the input side of the relay electrically disconnected have the same voltage level, that is, at the same low voltage level, and thus it is impossible to determine whether the relay is electrically disconnected). Hence, regarding the relay electrical disconnection response time r2 of the relay, the step of determining the relationship between the first electrical disconnection compensation time value T_{c1} and the half-wave period T_{hac} at point a5 further comprises: operating the controlling unit 101 when the first electrical disconnection compensation time value T_{c1} (that is, T_{c2} shown in FIG. 3) is not less than the half-wave period T_{hac} by taking the steps described hereunder, wherein the condition “the first electrical disconnection compensation time value T_{c1} being not less than the half-wave period T_{hac}” is equivalent to the determination that the relay electrical disconnection response time is larger than or equal to three times the T_{hac} value in step a2.
b1. enabling the relay upon determination that the phase timing on the input side of the relay matches a zero-voltage crossing point (that is, a point in time d) of switching from a high voltage level to a low voltage level;
b2. disabling the relay upon determination that the phase timing on the output side of the relay matches the point in time e of switching from a high voltage level to a low voltage level or when the phase timing on the input side of the enabled relay matches a zero-voltage crossing point (that is, the point in time e, also known as “a fourth start timing reference point”) again;
b3. obtaining a second electrical disconnection response time value Tᵣ₂ of the relay according to a temporal difference between the point in time e and the point in time g (that is, a second electrical disconnection timing reference point) of the disabled relay when the phase timing on the output side of the relay matches the point in time g of switching from a high voltage level to a low voltage level, and determining whether the relay is electrically disconnected against the criterion as to whether the phase timing on the input side of the relay arrives at a high voltage level (that is, the point in time f), followed by going to step b4 in response to an affirmative determination or going back to step b3 in response to a negative determination;
b4. obtaining a second electrical disconnection compensation time value T_{c2} of the relay according to a temporal difference between the point in time g and a point in time h in switching from a high voltage level to a low voltage level in the course of the phase timing on the output side of the relay, when the phase timing on the input side of the relay matches the point in time h of switching from a high voltage level to a low voltage level in the course of the phase timing on the input side of the relay; and
b5. determining the relationship between the second electrical disconnection compensation time value T_{c2} and the half-wave period T_{hac}, followed by determining that a time parameter required for the electrical disconnection of the relay includes the second electrical disconnection response time value Tᵣ₂ and the second electrical disconnection compensation time value T_{c2} when the second electrical connection compensation time value T_{c2} is less than the half-wave period T_{hac}.

Accordingly, the controlling unit 101 obtains a time parameter of the relay having the relay electrical disconnection response time r2 and stores the obtained time parameter therein. Afterward, every instance of demagnetization and resultant electrical disconnection of the relay results in a product of an even integral (exemplified by 2 in an embodiment of the present invention) and the half-wave period T_{hac}, with the product being equal to the sum of the second electrical disconnection response time value Tᵣ₂ and the second electrical disconnection compensation time value T_{c2}; hence, prior to the zero-voltage crossing point of the phase timing on the input side of the relay, the controlling unit 101 reaches the second electrical disconnection compensation time value T_{c2} and then controllably causes the driver 112 to demagnetize the relay 110. In doing so, a low voltage level occurs at the final point of electrical disconnection of the relay, thereby preventing a spark.

As shown in FIG. 3, regarding the relay electrical disconnection response time r3 of the relay, the step of determining the relationship between the first electrical disconnection compensation time value T_{c1} and the half-wave period T_{hac} at point a5 further comprises: operating the controlling unit 101 when the first electrical disconnection compensation time value T_{c1} (that is, as shown in FIG. 3, when the electrical disconnection compensation time value T_{c3} obtained in the first instance is not less than the half-wave period T_{hac}) is not less than the half-wave period T_{hac} by taking the steps of:
c1. enabling the relay upon determination that the phase timing on the input side of the relay matches a zero-voltage crossing point (that is, the point in time d) of switching from a high voltage level to a low voltage level;
c2. disabling the relay upon determination that the phase timing on the output side of the relay matches the point in time e of switching from a high voltage level to a low voltage level or upon determination that the phase timing on the input side of the enabled relay matches a zero-voltage crossing point (that is, the point in time e, also known as “a fifth start timing reference point”) again;
c3. obtaining a third electrical disconnection response time value Tᵣ₃ of the relay according to a temporal difference between the point in time e and the point in time fin switching from a high voltage level to a low voltage level during the phase timing on the output side of the relay upon determination that the phase timing on the input side of the relay matches a point in time of a high voltage level again but the phase timing on the output side of the relay does not match a point in time (that is, the point in time f, also known as “a third electrical disconnection timing reference point”) of a high voltage level;
c4. obtaining a third electrical disconnection compensation time value Tᵣ₃ of the relay according to a temporal difference between the point in time f and the point in time h as soon as the phase timing on the input side of the relay matches the point in time f of a high voltage level again, when the phase timing on the input side of the relay matches a zero-voltage crossing point (that is, the point in time h); and
c5. determining the relationship between the third electrical disconnection compensation time value T_{c3} and the half-wave period T_{hac}, followed by determining that a time parameter required for the electrical disconnection of the relay includes the third electrical connection response time value Tᵣ₃ and that the third electrical disconnection compensation time value T_{c3} equals zero when the third electrical connection compensation time value T_{c3} equals the half-wave period T_{hac} or equals two times the half-wave period T_{hac}.

Accordingly, the controlling unit 101 obtains a time parameter of the relay having the relay electrical disconnection response time r3 and stores the obtained time parameter therein. Considerations are given to the third electrical connection response time value Tᵣ₃ only in every instance of demagnetization and resultant electrical disconnection of the relay, because the relay electrical disconnection response time r3 of the relay equals the half-wave period T_{hac}. As a result, compensation-based control is not required, and thus the controlling unit 101 just needs to controllably causes the relay having the relay electrical disconnection response time r3 to have a demagnetization starting point that matches a zero-voltage crossing point of switching from a high voltage level to a low voltage level in the course of the phase timing on the input side of the relay; in doing so, a low voltage level occurs at the point in time of the demagnetization and result electrical disconnection of the relay having the relay electrical disconnection response time r3, thereby preventing a spark.

Accordingly, two equations for use in the calculation employed to implement a method for obtaining a time parameter according to the present invention are as follows:
1. The least multiple of T_{hac} (half-wave period)=T_{R} (electrical connection response time value)+T_{C} (electrical connection compensation time value); and
2. The least multiple of T_{hac} (half-wave period)=Tᵣ (electrical disconnection response time value)+T_{c} (electrical disconnection compensation time value).

According to the present invention, the two equations for use in the calculation are stored in a computer program product that can be installed on a computer at a production line and executed thereon. With the aforesaid equations and the aforesaid step of obtaining related parameters, it is feasible to calculate a response time parameter (including an electrical connection response time and an electrical disconnection response time) and a compensation time parameter (including an electrical connection compensation time value and an electrical disconnection compensation time value) of a relay.

In conclusion, a related time parameter of a relay can be obtained by means of the automatic operation of a controlling unit, such that a precise time parameter is assigned to each of the relays during the manufacturing process thereof, so as to facilitate the control exercised by the controlling unit and prevent a spark. Furthermore, the method of the present invention enables quick operation and a reduction in the manufacturing costs.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A method for obtaining a time parameter of timing in calibration of AC (alternating current) voltage level switching in a relay, the method comprising the steps of:
a. obtaining from an input side of the relay a half-wave period for use as an input source;
b. switching a state of the relay with a first point in time defined as the half-wave period as soon as the half-wave period of the phase timing on the input side of the relay matches a zero-voltage crossing point for switching between high and low voltage levels;
c. switching a state of the relay with a second point in time defined as the half-wave period as soon as the half-wave period of the phase timing on the output side of the relay matches a zero-voltage crossing point for switching between high and low voltage levels; and
d. switching a state of the relay with a third point in time defined as the half-wave period as soon as the half-wave period of the phase timing on the output side of the relay matches a zero-voltage crossing point for switching between high and low voltage levels;
wherein a response time parameter of the relay is obtained according to the first point in time and the second point in time, and a compensation time parameter of the relay is obtained according to the second point in time and the third point in time.

2. The method of claim 1,
wherein step b further comprises the sub-step of:
enabling the relay with a first start timing reference point defined as the first point in time as soon as the phase timing on the input side of the relay matches a zero-voltage crossing point of switching from a low voltage level to a high voltage level;
wherein step c further comprises the sub-steps of:
obtaining a first electrical connection response time value starting from the first start timing reference point to a first electrical connection timing reference point, wherein the first electrical connection timing reference point is a point in time when the phase timing on the output side of the relay matches a zero-voltage crossing point of switching from a low voltage level to a high voltage wherein the first electrical connection timing reference point is defined as the second point in time;
wherein step d further comprises the sub-steps of:
obtaining a first electrical connection compensation time value starting from the first electrical connection timing reference point to a timing reference point, wherein the timing reference point is a point in time when the phase timing on the output side of the relay matches a zero-voltage crossing point of switching from a high voltage level to a low voltage level, wherein the timing reference point is defined as the third point in time; and
determining a relationship between the first electrical connection compensation time value and the half-wave period, followed by determining that a time parameter required for electrical connection of the relay includes the first electrical connection response time value and the first electrical connection compensation time value when the first electrical connection compensation time value is less than the half-wave period.

3. The method of claim 2, wherein the sub-step of determining a relationship between the first electrical connection compensation time value and the half-wave period further comprises performing, upon determination that the first electrical connection compensation time value is not less than the half-wave period, the sub-steps of:
disabling the relay upon determination that the phase timing on one of the input side and the output side of the relay matches a zero-voltage crossing point of switching from a high voltage level to a low voltage level;
enabling the relay with a second start timing reference point defined as a zero-voltage crossing point of switching from a high voltage level to a low voltage level as soon as the phase timing on the input side of the relay matches the zero-voltage crossing point;
obtaining a second electrical connection response time value starting from the second start timing reference point to a second electrical connection timing reference point, wherein the second electrical connection timing reference point is a point in time when the phase timing on the output side of the relay matches a zero-voltage crossing point of switching from a low voltage level to a high voltage level;
obtaining a second electrical connection compensation time value starting from the second electrical connection timing reference point to a timing reference point, wherein the timing reference point is a point in time when the phase timing on the output side of the relay matches a zero-voltage crossing point of switching from a high voltage level to a low voltage level; and
determining a relationship between the second electrical connection compensation time value and the half-wave period, followed by determining that a time parameter required for electrical connection of the relay includes the second electrical connection response time value and the second electrical connection compensation time value when the second electrical connection compensation time value is less than the half-wave period.

4. The method of claim 3, wherein the sub-step of determining a relationship between the second electrical connection compensation time value and the half-wave period further comprises determining that a time parameter required for electrical connection of the relay is the second electrical connection response time value and that the second electrical connection compensation time value equals zero, when the second electrical connection compensation time value equals the half-wave period or equals two times the half-wave period.

5. The method of claim 2, further comprising the step of obtaining a time parameter required for electrical disconnection of the relay, wherein the step of obtaining a time parameter required for electrical disconnection of the relay further comprises the sub-steps of:
defining a third start timing reference point as a zero-voltage crossing point of switching from a low voltage level to a high voltage level, followed by disabling the electrically connected relay, as soon as the phase timing on one of the input side and the output side of the relay matches the zero-voltage crossing point;
obtaining the third electrical disconnection response time value starting from the first start timing reference point to the first electrical disconnection timing reference point, wherein the first electrical disconnection timing reference point is a point in time when the phase timing on the output side of the relay matches a zero-voltage crossing point of switching from a high voltage level to a low voltage level;
obtaining the first electrical disconnection compensation time value starting from the first electrical disconnection timing reference point to a timing reference point, wherein the timing reference point is a point in time when the phase timing on the input side of the relay matches a zero-voltage crossing point of switching from a high voltage level to a low voltage level; and
determining a relationship between the first electrical disconnection compensation time value and the half-wave period, followed by determining that a time parameter required for electrical disconnection of the relay includes the first electrical disconnection response time value and the first electrical disconnection compensation time value when the first electrical disconnection compensation time value is less than the half-wave period.

6. The method of claim 5, wherein the sub-step of obtaining the first electrical disconnection response time value further comprises determining whether the relay is electrically disconnected according to a voltage level of the output side of the relay when the phase timing on the input side of the relay matches a high voltage level.

7. The method of claim 5, wherein the sub-step of determining a relationship between the first electrical disconnection compensation time value and the half-wave period further comprises performing, upon determination that the first electrical disconnection compensation time value is not less than the half-wave period, the sub-steps of:
enabling the relay as soon as the phase timing on the input side of the relay matches a zero-voltage crossing point of switching from a high voltage level to a low voltage level;
disabling the relay with a fourth start timing reference point defined as a zero-voltage crossing point of switching from a high voltage level to a low voltage level upon determination that the phase timing on the output side of the relay matches the zero-voltage crossing point or upon determination that the phase timing on the input side of the relay matches the zero-voltage crossing point again;
obtaining a second electrical disconnection response time value starting from the fourth start timing reference point to a second electrical disconnection timing reference point, wherein the second electrical disconnection timing reference point is a point in time when the phase timing on the output side of the relay matches a zero-voltage crossing point of switching from a high voltage level to a low voltage level;
obtaining a second electrical disconnection compensation time value starting from the second electrical disconnection timing reference point to a timing reference point, wherein the timing reference point is a point in time when the phase timing on the input side of the relay matches a zero-voltage crossing point of switching from a high voltage level to a low voltage level; and
determining a relationship between the second electrical disconnection compensation time value and the half-wave period, followed by determining that a time parameter required for electrical disconnection of the relay includes the second electrical disconnection response time value and the second electrical disconnection compensation time value when the second electrical disconnection compensation time value is less than the half-wave period.

8. The method of claim 7, wherein the sub-step of obtaining a second electrical disconnection response time value further comprises determining whether the relay is electrically disconnected according to a voltage level of the output side of the relay when the phase timing on the input side of the relay matches a high voltage level.

9. The method of claim 5, wherein the sub-step of determining a relationship between the first electrical disconnection compensation time value and the half-wave period further comprises performing, upon determination that the first electrical disconnection compensation time value is not less than the half-wave period, the sub-steps of:
enabling the relay as soon as the phase timing on the input side of the relay matches a zero-voltage crossing point of switching from a high voltage level to a low voltage level;
disabling the relay with a fifth start timing reference point defined as a zero-voltage crossing point of switching from a high voltage level to a low voltage level upon determination that the phase timing on the output side of the relay matches the zero-voltage crossing point or upon determination that the phase timing on the input side of the relay matches the zero-voltage crossing point again;
obtaining a third electrical disconnection response time value starting from the fifth start timing reference point to a third electrical disconnection timing reference point, wherein the third electrical disconnection timing reference point is a point in time when the phase timing on the input side of the relay matches a high voltage level again and the phase timing on the output side of the relay does not match a high voltage level;
obtaining a third electrical disconnection compensation time value starting from the third electrical disconnection timing reference point to a timing reference point, wherein the timing reference point is a point in time when the phase timing on the input side of the relay matches a zero-voltage crossing point of switching from a high voltage level to a low voltage level; and
determining a relationship between the third electrical disconnection compensation time value and the half-wave period, followed by determining that a time parameter required for electrical disconnection of the relay is the third electrical disconnection response time value and that the third electrical disconnection compensation time value equals zero, when the third electrical disconnection compensation time value equals the half-wave period or equals two times the half-wave period.

10. The method of claim 9, wherein the sub-step of obtaining a third electrical disconnection response time value further comprises determining whether the relay is electrically disconnected according to a voltage level of the output side of the relay when the phase timing on the input side of the relay matches a high voltage level.

11. The method of claim 1, wherein, on the input side of the relay, an input source of an AC sine wave is transformed into a half-wave rectified square wave so as to obtain the half-wave period.

12. A computer program product stored therein with a time parameter for obtaining timing in calibration of AC (alternating current) voltage level switching in a relay so as to implement the method of claim 1 after the computer program is installed on a computer and executed thereon, so as to obtain a response time parameter and a compensation time parameter of the relay according to a least multiple of a half-wave period.
